(19) United States
(12) Patent Application Publication
(10) Pub. No.: US 2024/0240300 A1
(43) Pub. Date: Jul. 18, 2024

(54) RESTORING METHOD FOR INNER WALL MEMBER OF PLASMA PROCESSING APPARATUS

(71) Applicant: Hitachi High-Tech Corporation, Minato-ku, Tokyo (JP)

(72) Inventors: Shoichiro Mizunashi, Tokyo (JP); Tadayoshi Kawaguchi, Tokyo (JP); Taku Watanabe, Tokyo (JP)

(21) Appl. No.: 17/797,267

(22) PCT Filed: Jun. 28, 2021
(86) PCT No.: PCT/JP2021/024419

§ 371 Date: Aug. 3, 2022

(51) Int. Cl. C23C 4/02; H01J 37/32

(52) U.S. Cl. CPC C23C 4/02; H01J 37/32495

(57) ABSTRACT

An inner wall member 40 provided on an inner wall of a processing chamber, in which plasma processing is performed, includes a base material 41, an anodized film 42a having an end EP1, and a sprayed film 42b having an end EP2. The base material 41 includes a surface FS1, a surface FS2 located at a higher position than the surface FS1, and a side surface SS1. A method for restoring the inner wall member 40 includes the steps of (a) covering by a mask material 100 the anodized film 42a exposed from the sprayed film 42b, (b) performing blasting on the sprayed film 42b to remove the sprayed film 42b on the surface FS2 while partially leaving the sprayed film 42b on the surface FS1 and the side surface SS1 such that the anodized film 42a being not covered with the mask material 100 is covered by the sprayed film 42b, (c) forming a new sprayed film 42b by spraying on the left sprayed film 42b and the surface FS2, and (d) removing the mask material 100.

### TECHNICAL FIELD

The present invention relates to a method for restoring an inner wall member, specifically relates to a method for restoring an inner wall member provided on an inner wall of a processing chamber, in which plasma processing is performed, of a plasma processing apparatus.

### BACKGROUND ART

An integrated circuit has been formed by a plurality of film layers stacked on a surface of a semiconductor wafer in a process of processing the semiconductor wafer to manufacture an electronic device, for example. For such a manufacturing process, fine processing is required, and an etching process using plasma is used. In the processing using such a plasma etching process, higher accuracy and a higher yield are required with an increase in degree of integration of an electronic device.

A plasma processing apparatus to perform a plasma etching process has a processing chamber, in which plasma is generated, in the inside of a vacuum container. A semiconductor wafer is accommodated within the processing chamber. A member constituting an inner wall of the processing chamber typically includes a base material including a metal material such as aluminum or stainless steel for reason of strength and manufacturing cost. Further, the inner wall of the processing chamber is in contact with or faces plasma during plasma processing. Hence, the member constituting the inner wall of the processing chamber has a coating having high plasma resistance disposed on a surface of the base material. The coating protects the base material from plasma.

A method for forming a sprayed film by so-called spraying has been known as a technique for forming such a coating. In the spraying, plasma is generated in a gas atmosphere adjusted to atmospheric pressure or a certain pressure, and particles of a material for the coating are injected into the plasma to form semi-molten particles. Such semi-molten particles are sprayed or applied on a surface of the base material to form the sprayed film.

For example, a ceramic material such as aluminum oxide, yttrium oxide, or yttrium fluoride, or a material containing such a ceramic material is used as a material of the sprayed film. Such a coating (sprayed film) covers the surface of the base material, thereby the member constituting the inner wall of the processing chamber is, over a long period, reduced in wear by plasma, reduced in amount of interaction between the plasma and the member surface, and reduced in change in properties.

For example, Patent Literature 1 discloses a member, which has a coating having such plasma resistance, of an inner wall of a processing chamber. Patent Literature 1 discloses a yttrium oxide coating as one example of the coating.

On the other hand, the surface of the sprayed film is problematically degenerated after long use, and thus particles of the sprayed film are worn due to interaction with plasma, resulting in a reduction in thickness of the sprayed film. If a surface of the base material is exposed in the inside of the processing chamber, particles of the metal material constituting the base material may be deposited on a wafer to be processed within the processing chamber, leading to contamination of the wafer. Hence, a sprayed film is typically restored by spraying on a surface of a member having a sprayed film that is degenerated, damaged, or worn through use.

### CITATION LIST

### Patent Literature

Patent Literature 1: Japanese Unexamined Patent Application Publication No. 2004-100039.

### SUMMARY OF INVENTION

### Technical Problem

Unfortunately, existing techniques have insufficiently considered the followings, leading to various problems.

In the existing techniques, for example, when a sprayed film is restored by spraying, thickness of the sprayed film is difficult to be maintained constant before and after the respraying.

When the base material is aluminum or an aluminum alloy, an alumite coating (anodized film) formed by anodizing and a coating (sprayed film) formed by spraying are provided on a surface of the base material. A boundary is formed between the anodized film and the sprayed film. Specifically, the sprayed film is formed over the anodized film so as to cover an end of the anodized film. In such a case, when the degenerated sprayed film is removed, the anodized film covered with the sprayed film is also removed, and thus a position of the end of the anodized film is retracted. Hence, the position of the end of the anodized film is retracted every repetitive restoration of a sprayed film, resulting in a reduction in area of the anodized film.

On the other hand, if the sprayed film is removed so as to leave the end of the anodized film, a previous sprayed film, which has been degenerated or worn, is left on the anodized film. Hence, the left previous sprayed film is stacked every repetitive restoration of the sprayed film. Since such a stacked body of the previous sprayed films is readily separated, the stacked body may become a source of a foreign matter within the processing chamber.

A major object of this application is to provide a technique enabling thickness of the sprayed film to be maintained before and after respraying. Another object of this application is to provide a technique that can prevent a decrease in area of the anodized film and suppress generation of a foreign matter within the processing chamber.

Other problems and novel features will be clarified from the content of this description and the accompanied drawings.

### Solution to Problem

Typical embodiments disclosed in this application are briefly summarized as follows.

A method for restoring an inner wall member in one embodiment is a method for restoring an inner wall member provided on an inner wall of a processing chamber, in which plasma processing is performed, of a plasma processing apparatus. The inner wall member includes a base material having a first surface, a second surface located at a higher position than the first surface, and a first side surface connecting the first surface to the second surface, an anodized film formed on the first surface and the first side surface, and having a first end located on the first side surface, and a first sprayed film formed on the first surface, the first side surface, and the second surface so as to cover the first end, and having a second end located on the anodized film formed on the first surface. The method for restoring the inner wall member includes the steps of (a) covering by a mask material the anodized film exposed from the first sprayed film, (b) after the step (a), performing blasting on the first sprayed film to remove the first sprayed film on the second surface while partially leaving the first sprayed film on the first surface and the first side surface such that the anodized film being not covered with the mask material is covered by the first sprayed film, (c) after the step (b), forming a second sprayed film by spraying on the left first sprayed film and the second surface, and (d) after the step (c), removing the mask material.

A method for restoring an inner wall member in another embodiment is a method for restoring an inner wall member provided on an inner wall of a processing chamber, in which plasma processing is performed, of a plasma processing apparatus. The inner wall member includes a base material having a first surface, a second surface located at a higher position than the first surface, and a first side surface connecting the first surface to the second surface, an anodized film formed on the first surface, the first side surface, and the second surface, and having a first end located on the first surface, and a first sprayed film formed on the first surface so as to cover the first end, and having a second end located on the anodized film formed on the first surface. The method for restoring the inner wall member includes the steps of (a) covering by a mask material the anodized film exposed from the first sprayed film and formed at least on the first surface and the first side surface, (b) after the step (a), performing blasting on the first sprayed film to remove the first sprayed film on the first surface, (c) after the step (b), forming a second sprayed film by spraying on the first surface exposed from the mask material, and (d) after the step (c), removing the mask material.

### Advantageous Effects of Invention

According to one embodiment, it is possible to maintain thickness of the sprayed film to be constant before and after respraying. It is further possible to prevent a decrease in area of the anodized film and suppress generation of a foreign matter within the processing chamber.

### BRIEF DESCRIPTION OF DRAWINGS

FIG. 1 is a schematic diagram illustrating a plasma processing apparatus of a first embodiment.

FIG. 2 is a conceptual diagram illustrating an inner wall member in the first embodiment.

FIG. 3 is a plan diagram illustrating the inner wall member in the first embodiment.

FIG. 4 is a cross-sectional diagram illustrating the inner wall member in the first embodiment.

FIG. 5A is a cross-sectional diagram illustrating a base material of the inner wall member in the first embodiment.

FIG. 5B is a cross-sectional diagram illustrating a method for restoring the inner wall member in the first embodiment.

FIG. 5C is a cross-sectional diagram illustrating the method for restoring the inner wall member following FIG. 5B.

FIG. 5D is a cross-sectional diagram illustrating the method for restoring the inner wall member following FIG. 5C.

FIG. 6A is a cross-sectional diagram illustrating a base material of an inner wall member in a second embodiment.

FIG. 6B is a cross-sectional diagram illustrating a mask material in the second embodiment.

FIG. 6C is a cross-sectional diagram illustrating a method for restoring the inner wall member in the second embodiment.

FIG. 6D is a cross-sectional diagram illustrating the method for restoring the inner wall member following FIG. 6C.

FIG. 6E is a cross-sectional diagram illustrating the method for restoring the inner wall member following FIG. 6D.

### DESCRIPTION OF EMBODIMENTS

Some embodiments are now described in detail with reference to drawings. In all drawings for explaining the embodiments, components having the same function are designated by the same sign, and duplicated description is omitted. In the embodiments, the same or similar portion is not repeatedly described in principle except for a particularly required case

The X direction, Y direction, and 2 direction described in this application intersect one another and are orthogonal to each other. The expression “plan view” used in this application means Z-directional view of a plane defined by the X direction and the Y direction.

### First Embodiment

### Configuration of Plasma Processing Apparatus

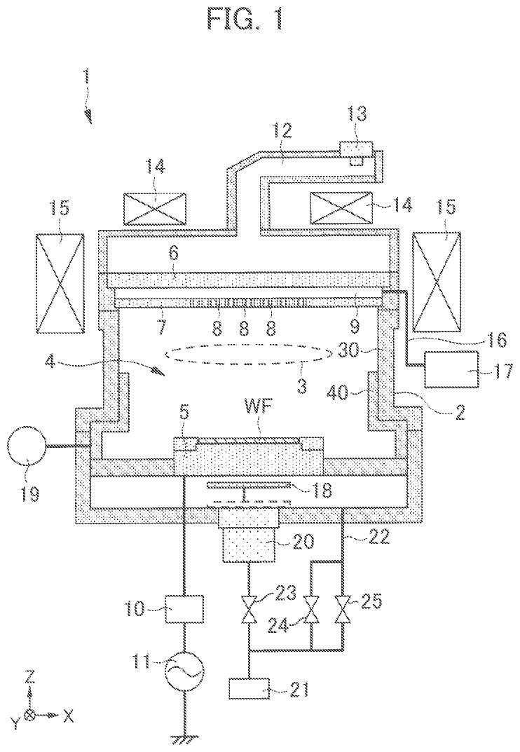

A plasma processing apparatus 1 of a first embodiment is now summarized with FIG. 1.

The plasma processing apparatus 1 includes a cylindrical vacuum container 2, a processing chamber 4 provided in the inside of the vacuum container 2, and a stage 5 provided in the inside of the processing chamber 4. The upper part of the processing chamber 4 forms a discharge room being a space in which plasma 3 is generated.

A disc-shaped window member 6 and a disc-shaped plate 7 are provided above the stage 5. The window member 6 is made of a dielectric material such as, for example, quartz or ceramics, and hermetically seals the inside of the processing chamber 4. The plate 7 is provided below the window member 6 so as to be separated from the window member 6, and is made of a dielectric material such as, for example, quartz. The plate 7 has a plurality of through-holes 8. A gap 9 is provided between the window member 6 and the plate 7, and a processing gas is supplied into the gap 9 during plasma processing.

The stage 5 is used to place a wafer (substrate) WF thereon during performing plasma processing on the wafer WF being a material to be processed. The wafer WF includes, for example, a semiconductor material such as silicon. The stage 5 is a cylindrical member, of which the vertical central axis is disposed at a position, at which the stage 5 is concentric with or considered to be approximately concentric with a charge room of the processing chamber 4 as viewed from the above.

The space between the stage 5 and the bottom of the processing chamber 4 is in communication with a space above the stage 5 via a gap between a sidewall of the stage 5 and a side surface of the processing chamber 4. Thus, a product generated during processing of the wafer WF placed on the stage 5, the plasma 3, or gas particles is/are discharged to the outside of the processing chamber 4 via the space between the stage 5 and the bottom of the processing chamber 4.

While not shown in detail, the stage 5 has a cylindrical shape and includes a base material including a metal material. The upper surface of the base material is covered with a dielectric film. A heater is provided in the inside of the dielectric film, and a plurality of electrodes are provided above the heater. A DC voltage is supplied to the respective electrodes. The DC voltage allows the wafer WF to be adsorbed onto the upper surface of the dielectric film, and allows electrostatic force for holding the wafer WF to be generated in the inside of the dielectric film and in the inside of the wafer WF. The electrodes are arranged point-symmetrically around the vertical central axis of the stage 5, and receives voltages the polarities of which are different from each other.

The stage 5 has a coolant channel disposed concentrically or spirally in a multiple manner. A heat-conductive gas such as helium (He) is supplied into a gap between the lower surface of the wafer WF and the upper surface of the dielectric film in a state where the wafer WF is placed on the upper surface of the dielectric film. A pipe is thus disposed in the inside of the base material and in the inside of the dielectric film to pass the gas through the pipe.

The plasma processing apparatus 1 includes an impedance matching device 10 and a high-frequency power source 11. The base material of the stage 5 is connected to the high-frequency power source 11 via the impedance matching device 10. During plasma processing of the wafer WF, the high-frequency power source 11 supplies high-frequency power to the base material to generate an electric field to attract charged particles in the plasma onto the upper surface of the wafer WF.

The plasma processing apparatus 1 includes a waveguide 12, a magnetron oscillator 13, a solenoid coil 14, and a solenoid coil 15. The waveguide 12 is provided above the window member 6. The magnetron oscillator 13 is provided at one end of the waveguide 12. The magnetron oscillator 13 can output an oscillating electric field of a microwave. The waveguide 12 is a conduit for propagating the microwave electric field. The microwave electric field is supplied into the processing chamber 4 via the waveguide 12. The solenoid coils 14 and 15 are provided around the waveguide 12 and the processing chamber 4, respectively, and are each used as a magnetic-field generation unit.

The waveguide 12 has a square waveguide part and a circular waveguide part. The square waveguide part has a rectangular sectional shape and extends in a horizontal direction. The magnetron oscillator 13 is provided at one end of the square waveguide part. The circular waveguide part is connected to the other end of the square waveguide part. The circular waveguide part has a circular sectional shape, and is configured to have a central axis extending in a vertical direction.

The plasma processing apparatus 1 includes a pipe 16 and a gas supply unit 17. The gas supply unit 17 is connected to the processing chamber 4 via the pipe 16. The processing gas is supplied into the gap 9 from the gas supply unit 17 via the pipe 16 and diffuses within the gap 9. The diffused processing gas is supplied to the space above the stage 5 through the through-holes 8.

The plasma processing apparatus 1 includes a pressure regulating plate 18, a pressure detector 19, a turbo molecular pump 20 being a high-vacuum pump, a dry pump 21 being a roughing pump, an exhaust pipe 22, and valves 23 to 25. A space between the stage 5 and the bottom of the processing chamber 4 serves as an evacuation part. The pressure regulating plate 18, which is a disc-shaped valve, vertically moves above an exhaust port and thus increases or decreases area of a channel through which gas flows into the exhaust port. That is, the pressure regulating plate 18 also serves as a valve to open or close the exhaust port.

The pressure detector 19 is a sensor to detect internal pressure of the processing chamber 4. A signal output from the pressure detector 19 is transmitted to an undepicted controller that then detects a value of the pressure and outputs a command signal according to the detected value. The pressure regulating plate 18 is driven according to the command signal and changes its vertical position to increase or decrease area of the exhaust channel.

An outlet of the turbo molecular pump 20 is connected to the dry pump 21 via a pipe. A valve 23 is provided in the middle of the pipe. The space between the stage 5 and the bottom of the processing chamber 4 is connected to the exhaust pipe 22 for which valves 24 and 25 are provided. The valve 24 is a slow exhaust valve for slow exhaust by the dry pump 21 to evacuate the processing chamber 4 from atmospheric pressure. The valve 23 is a main exhaust valve for fast exhaust by the turbo molecular pump 20.

### Plasma Processing

An exemplary case of plasma processing is now given, in which an etching process using the plasma 3 is performed on a predetermined film beforehand formed on the upper surface of the wafer WF.

The wafer WF is transferred from the outside of the plasma processing apparatus 1 into the processing chamber 4 while being placed on a tip end of an arm, such as a robot arm, of a vacuum transfer system, and is set on the stage 5. When the arm of the vacuum transfer system exits from the processing chamber 4, the inside of the processing chamber 4 is sealed. A DC voltage is applied to an electrode for electrostatic adsorption in the dielectric film on the stage 5, and the wafer WF is held on the dielectric film by the generated electrostatic force.

In this state, the heat-conductive gas such as helium (He) is supplied into the gap between the wafer WF and the dielectric film via a pipe provided in the stage 5. A coolant adjusted at a predetermined temperature by an undepicted coolant temperature regulator is supplied into a coolant channel in the stage 5. Heat conduction is thus prompted between the base material adjusted in temperature and the wafer WF, and thus temperature of the wafer WF is adjusted to a value within a range appropriate for start of plasma processing.

A processing gas adjusted in flow rate and speed by the gas supply unit 17 is supplied into the processing chamber 4 via the pipe 16, while the gas in the processing chamber 4 is exhausted from the exhaust port by operation of the turbo molecular pump 20. Such gas supply and gas exhaust are balanced to adjust internal pressure of the processing chamber 4 to a value within a range appropriate for plasma processing.

In such a state, the magnetron oscillator 13 outputs an oscillating electric field of a microwave. The microwave electric field propagates within the waveguide 12 and is transmitted by the window member 6 and the plate 7. Further, magnetic fields generated by the solenoid coils 14 and 15 are supplied to the processing chamber 4. Electron cyclotron resonance (ECR) is induced by interaction of the magnetic field and the microwave electric field. The plasma 3 is generated within the processing chamber 4 by excitation, ionization, or dissociation of atoms or molecules of the processing gas.

When the plasma 3 is generated, the high-frequency power source 11 supplies high-frequency power to the base material of the stage 5, so that a bias potential is generated over the upper surface of the wafer WE, and thus charged particles such as ions in the plasma 3 are attracted to the upper surface of the wafer WF. As a result, an etching process is performed on the predetermined film on the wafer WF along a pattern shape of a mask layer. Subsequently, when it is detected that processing of the objective film reaches the endpoint, the high-frequency power source 11 stops supply of the high-frequency power, so that the plasma processing is stopped.

If a further etching process of the wafer WF is not required, evacuation is performed. Static electricity is then removed and adsorption of the wafer WF is released, and then the arm of the vacuum transfer system enters the processing chamber 4 to transfer the processed wafer WF to the outside of the plasma processing apparatus 1.

### Inner Wall Member of Processing Chamber

As illustrated in FIG. 1, an inner wall member 40 is provided within the processing chamber 4. The inner wall member 40 serves as, for example, an earth electrode for stabilizing an electric potential of the plasma 3 being a dielectric.

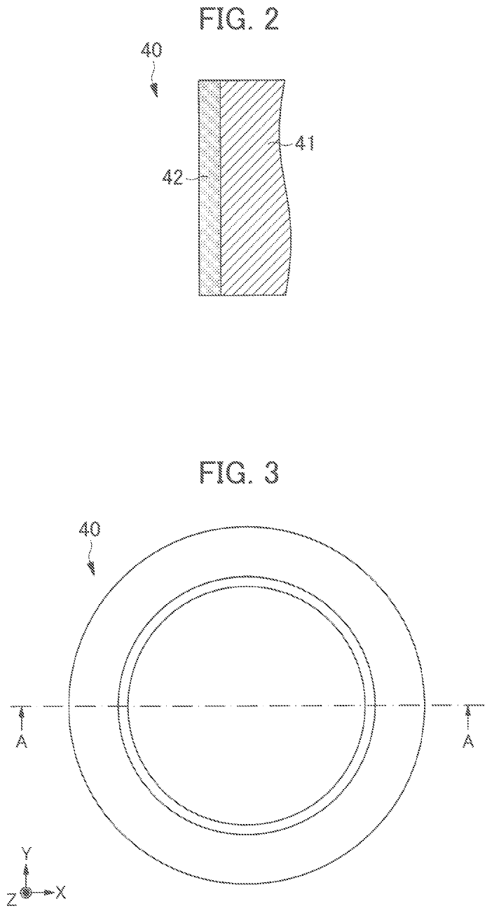

As illustrated in FIG. 2, the inner wall member 40 includes a base material 41 and a coating 42 covering a surface of the base material 41. The base material 41 includes a conductive material such as a metal material, for example, aluminum, aluminum alloy, stainless steel, or stainless steel alloy.

The inner wall member 40 is exposed to the plasma 3 during plasma processing. If the coating 42 does not exist on the surface of the base material 41, the base material 41 is exposed to the plasma 3 and thus may be a source of corrosion or a foreign matter, leading to contamination of the wafer WF. The coating 42 is provided to suppress contamination of the wafer WF and includes a material having higher resistance to the plasma 3 than the base material 41. The coating 42 allows the function of the inner wall member 40 as the earth electrode to be maintained, and allows the base material 41 to be protected from the plasma 3.

A base material 30, which does not have the function of the earth electrode, also includes a metal material such as stainless steel alloy or aluminum alloy. A surface of the base material 30 is therefore also subjected to processing for improving resistance to the plasma 3 or processing for reducing wear of the base material 30 in order to suppress corrosion or generation of a foreign matter caused by exposure to the plasma 3. Examples of such processing include passivation treatment, formation of a sprayed film, and film formation by physical vapor deposition (PVD) or chemical vapor deposition (CVD).

While not shown, a cylindrical cover made of ceramic such as yttrium oxide or quartz may be disposed on the inside of the inner wall of the cylindrical base material 30 to reduce wear of the base material 30 by the plasma 3. Disposing such a cover between the base material 30 and the plasma 3 blocks or reduces contact between the base material 30 and highly reactive particles in the plasma 3 or collision between the base material 30 and charged particles. As a result, wear of the base material 30 can be suppressed.

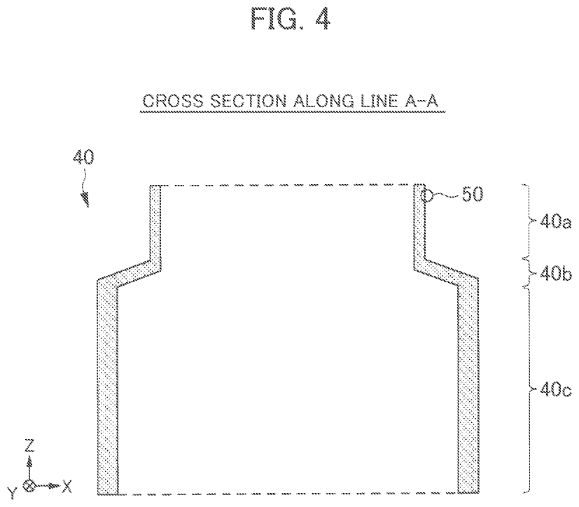

A configuration of the inner wall member 40 is described with FIGS. 3 and 4. FIG. 3 is a plan diagram illustrating the inner wall member 40. FIG. 4 is a cross-sectional diagram along a line A-A in FIG. 3.

The inner wall member 40 (base material 41) roughly has a cylinder shape having a certain thickness between the inner circumference and the outer circumference of the cylinder. The inner wall member 40 is configured of an upper part 40a, an intermediate part 40b, and a lower part 40c. The upper part 40a is a portion at which the inner diameter and the outer diameter of the cylinder are each relatively small, and the lower part 40c is a portion at which the inner diameter and the outer diameter of the cylinder are each relatively large. The intermediate part 40b is a portion to connect the upper part 40a to the lower part 40c, and has a truncated cone shape in which the inner diameter and the outer diameter of the cylinder are each continuously changed.

The inner wall member 40 is provided along the inner wall of the processing chamber 4 so as to enclose the outer circumference of the stage 5. A sprayed film is formed by spraying as part of the coating 42 on a surface on the inner circumferential side of the inner wall member 40 (surface on the inner circumferential side of the base material 41). In a state where the inner wall member 40 is attached to the inside of the processing chamber 4, an anodized film is formed by anodizing as part of the coating 42 on the surface on the outer circumferential side of the inner wall member 40 (surface on the outer circumferential side of the base material 41).

The sprayed film is formed on the surface not only on the inner circumferential side but also on the outer circumferential side of the base material 41 via an upper end of the upper part 40a. The reason for this is as follows: At the upper part 40a, particles of the plasma 3 may come around from the inner circumferential side to the outer circumferential side of the inner wall member 40 and interact with the surface on the outer circumferential side of the base material 41. Hence, the sprayed film needs to be formed on the surface on the outer circumferential side of the base material 41 up to a region to which the particles of the plasma 3 are assumed to come around. In FIG. 4, such a region is designated as a region 50.

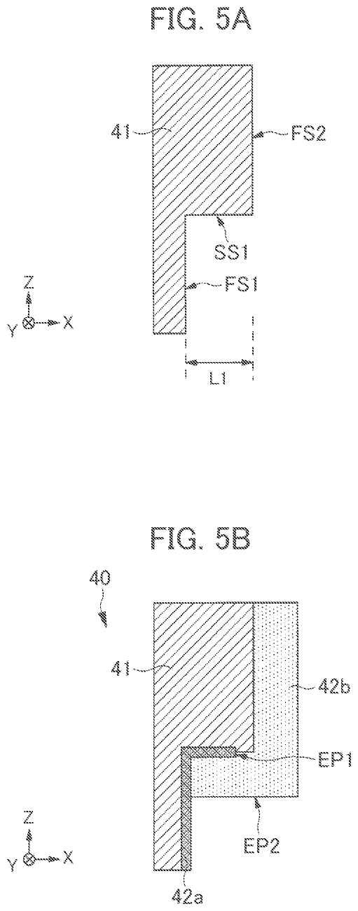

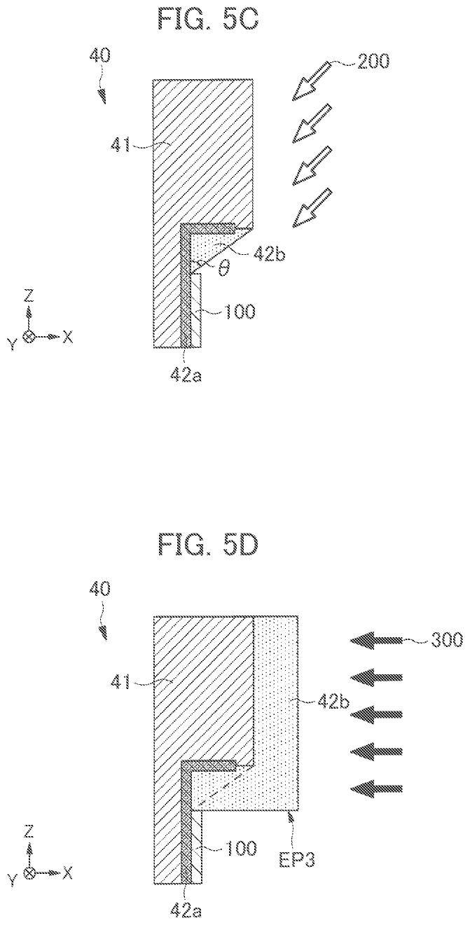

FIGS. 5A to 5D are each a cross-sectional diagram illustrating the region 50 in an enlarged manner. The inner wall member 40 in the first embodiment includes the base material 41, an anodized film 42a, and a sprayed film 42b as described below. FIG. 5A illustrates the base material 41 before formation of the coating 42 (anodized film 42a and sprayed film 42b). FIG. 5B illustrates the base material 41 after formation of the coating 42.

As illustrated in FIG. 5A, the base material 41 in the first embodiment has a step in a direction (X direction) from the inner circumferential side of the inner wall member 40 (inner circumferential side of the base material 41) toward the outer circumferential side of the inner wall member 40 (outer circumferential side of the base material 41). Specifically, the base material 41 has, on its outer circumferential side, a surface FS1, a surface FS2 located at a position higher than the surface FS1, and a side surface SS1 connecting the surface FS1 to the surface FS2. A distance L1 between the surfaces FS1 and FS2 corresponds to height of the step and to length of the side surface SS1. In this case, the distance L1 is, for example, 0.5 mm.

As illustrated in FIG. 5B, the anodized film 42a is formed on the surface FS1 and the side surface SS1. The anodized film 42a has an end EP1 located on the side surface SS1. The anodized film 42a is formed by anodizing before formation of the sprayed film 42b. When the base material 41 includes, for example, aluminum or aluminum alloy, the anodized film 42a includes an alumite coating.

The sprayed film 42b is formed on the surface FS1, the side surface SS1, and the surface FS2 so as to cover the end EP1. The sprayed film 42b has an end EP2 located on the anodized film 42a formed on the surface FS1.

The sprayed film 42b is formed by spraying using plasma, for example. In such spraying, plasma is generated under atmospheric pressure, and particles of yttrium oxide, yttrium fluoride, or a material containing yttrium oxide and/or yttrium fluoride are supplied into the plasma and made into a semi-molten state. Such semi-molten particles are blown or applied to the surfaces FS1 and FS2 of the base material 41 to form the sprayed film 42b.

Irregularity of the surface of the sprayed film 42b is designed to have an arithmetic average roughness (surface roughness) Ra of 8 or less, for example. The average size of particles (average particle diameter) of the sprayed film 42b is, for example, 10 to 50 μm in volume basis (D50).

In the region 50, the surface FS1, the side surface SS1, and the surface FS2 of the base material 41 are each covered with the anodized film 42a and/or the sprayed film 42b. This prevents the base material 41 from being exposed to the plasma 3 during plasma processing.

### Method for Restoring Inner Wall Member in First Embodiment

Steps of a method for restoring the inner wall member 40 (method for manufacturing the inner wall member 40) are now described with FIGS. 5B to 5D.

The inner wall member 40 of FIG. 5B is disposed in the processing chamber 4 and exposed to the plasma 3 during a predetermined period. Since the sprayed film 42b exposed to the plasma 3 is changed in properties or worn, it is necessary to remove such a sprayed film 42b and restore a sprayed film 42b.

First, as illustrated in FIG. 5C, the anodized film 42a exposed from the sprayed film 42b is covered by a mask material 100. At this time, the mask material 100 is in contact with the end EP2 of the sprayed film 42b. The mask material 100 includes a material that is characteristically not removed by blasting as described later, and is, for example, a resin tape.

Subsequently, blasting is performed on the sprayed film 42b. The blasting is performed by projecting blast particles 200 from a direction running from the surface FS2 toward the surface FS1 and inclined at a certain angle θ with respect to the surface FS1. The blast particles 200 collide with particles of the sprayed film 42b, and thus the sprayed film 42b is removed by a physical effect. The sprayed film 42b can be partially left by appropriately selecting the angle θ of the projected blast particles 200.

Such blasting removes the sprayed film 42b on the surface FS2 while partially leaving the sprayed film 42b on the surface FS1 and the side surface SS1 such that part of the anodized film 42a, which is not covered with the mask material 100, is covered by the sprayed film 42b. As described above, since the anodized film 42a is covered with either the left sprayed film 42b or the mask material 100, the anodized film 42a is not entirely exposed to the blasting.

Subsequently, as illustrated in FIG. 5D, a new sprayed film 42b is formed by spraying on the left sprayed film 42b and the surface FS2. A method and a condition for forming the new sprayed film 42b are the same as those described with reference to FIG. 5B. A direction in which the semi-molten particles 300 are blown to the surfaces FS1 and FS2 of the base material 41 is perpendicular to the surfaces FS1 and FS2. Subsequently, the mask material 100 is removed. Since the sprayed film 42b can be restored in this way, the inner wall member 40 is restored into the state of FIG. 5B.

The newly formed sprayed film 42b in FIG. 5D has an end EP3 located on the anodized film 42a formed on the surface FS1. A position of the end EP3 corresponds to the position of the end EP2 of the sprayed film 42b in FIG. 5B.

The initially formed sprayed film 42b and the newly formed sprayed film 42b are made of the same material. A portion of the sprayed film 42b left after blasting is not directly exposed to the plasma 3 during blasting and is thus substantially not changed in properties. The left sprayed film 42b and the new sprayed film 42b are integrated as a homogenous and good sprayed film 42b.

After that, if the inner wall member 40 is exposed to the plasma 3 again so that the sprayed film 42b is, for example, changed in properties, the steps of FIGS. 5B to 5D are repeated, thereby the sprayed film 42b can be restored and in turn the inner wall member 40 can be restored.

As described above, a problem has been existed in the existing technique: Since a position of the end EP1 of the anodized film 42a is retracted every time the sprayed film 42b is repeatedly restored, area of the anodized film 42a is decreased. In addition, when the sprayed film 42b is removed so as to leave the end EP1 of the anodized film 42a, the left previous sprayed film 42b is stacked every time the sprayed film 42b is repeatedly stored, and such a stacked body problematically becomes a source of a foreign matter within the processing chamber.

On the other hand, in the first embodiment, the position of the end EP1 of the anodized film 42a is not changed before and after restoration of the sprayed film 42b. It is therefore possible to prevent area of the anodized film 42a from being decreased, and suppress generation of a foreign matter within the processing chamber 4. Further, the position of the end EP3 of the newly formed sprayed film 42b in FIG. 5D corresponds to the position of the end EP2 of the sprayed film 42b in FIG. 5B. That is, a sprayed film 42b can be provided such that various parameters, such as thickness and area, are each substantially the same before and after respraying.

### Second Embodiment

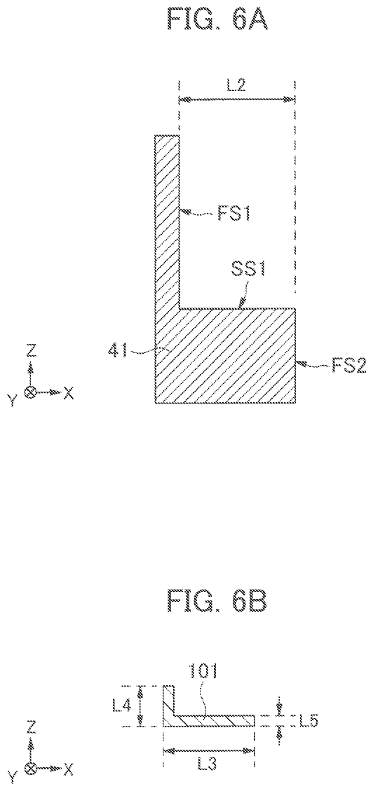

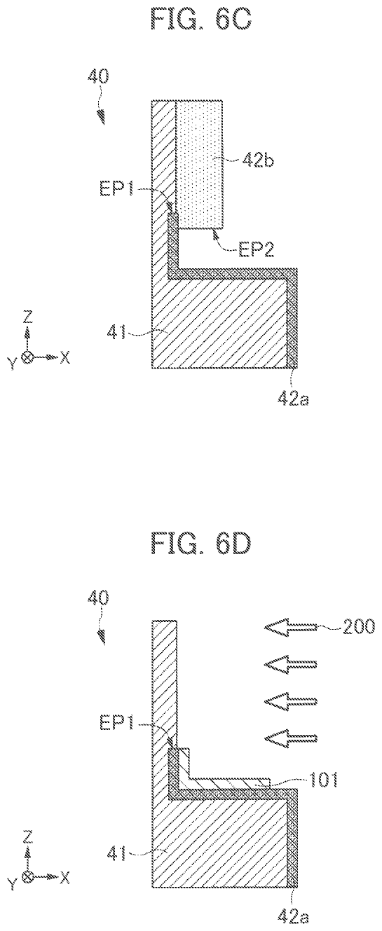

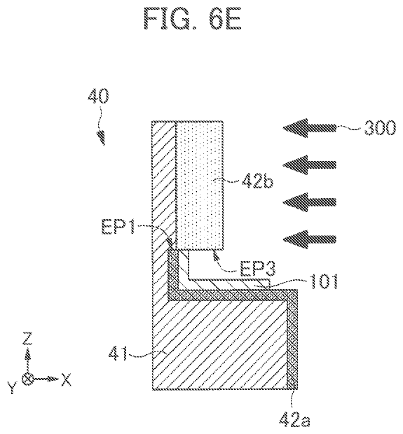

An inner wall member 40 and a method for restoring the inner wall member 40 (method for manufacturing the inner wall member 40) in a second embodiment are now described with FIGS. 6A to 6E. In the following, differences from the first embodiment are mainly described, and duplicated description is omitted.

### Inner Wall Member in Second Embodiment

FIGS. 6A to 6E are each a cross-sectional diagram illustrating the region 50 in FIG. 4 in an enlarged manner. As in the first embodiment, the inner wall member 40 in the second embodiment also includes the base material 41, the anodized film 42a, and the sprayed film 42b. Respective materials constituting such components and respective methods for forming the components are the same as those in the first embodiment.

FIG. 6A illustrates the base material 41 before formation of the coating 42 (anodized film 42a and sprayed film 42b). FIG. 6B illustrates a mask material 101 used in the second embodiment. FIG. 6C illustrates the base material 41 after formation of the coating 42.

As illustrated in FIG. 6A, the base material 41 in the second embodiment also has a step in a direction (X direction) from the inner circumferential side of the inner wall member 40 (inner circumferential side of the base material 41) toward the outer circumferential side of the inner wall member 40 (outer circumferential side of the base material 41). A distance L2 between the surfaces FS1 and FS2 corresponds to height of the step and to length of the side surface SS1. In this case, the distance L2 is, for example, 5.0 mm.

As illustrated in FIG. 6B, the mask material 101 in the second embodiment is an L-shaped metal member that is beforehand produced so as to correspond to a shape of the step. Specifically, the mask material 101 is a jig having a shape following the respective shapes of the surface FS1 and the side surface SS1, and includes a metal material. A distance L3 of a portion of the mask material 101 along the side surface SS1 is designed to be slightly smaller than the distance L2, and is, for example, 4.5 mm. A portion of the mask material 101 along the surface FS1 is designed to be closer to the side surface SS1 than an end EP1 of the anodized film 42a, and is, for example, 2.0 mm. The mask material 101 has a thickness L5 of, for example, 1.0 mm.

As illustrated in FIG. 6C, the anodized film 42a in the second embodiment is formed on the surface FS1, the side surface SS1, and the surface FS2. The anodized film 42a has the end EP1 located on the surface FS1. The sprayed film 42b is formed on the surface FS1 so as to cover the end EP1. The sprayed film 42b has an end EP2 located on the anodized film 42a formed on the surface FS1.

In the region 50 in the second embodiment, the surface FS1, the side surface SS1, and the surface FS2 of the base material 41 are each also covered with the anodized film 42a and/or the sprayed film 42b, and thus the base material 41 is prevented from being exposed to the plasma 3 during plasma processing.

### Method for Restoring Inner Wall Member in Second Embodiment

Steps of a method for restoring the inner wall member 40 (method for manufacturing the inner wall member 40) are now described with FIGS. 6C to 6E.

The inner wall member 40 of FIG. 6C is disposed in the processing chamber 4 and exposed to the plasma 3 during a predetermined period. Since the sprayed film 42b exposed to the plasma 3 is changed in properties or worn, it is necessary to remove such a sprayed film 42b and restore a sprayed film 42b.

First, as illustrated in FIG. 6D, the anodized film 42a, which is exposed from the sprayed film 42b and formed at least on the surface FS1 and the side surface SS1, is covered by the mask material 101. At this time, the mask material 101 is in contact with the end EP2 of the sprayed film 42b.

Subsequently, blasting is performed on the sprayed film 42b to remove the sprayed film 42b on the surface FS1. The blasting is performed by projecting blast particles 200 from a direction perpendicular to the surface FS1. The blast particles 200 collide with particles of the sprayed film 42b, and thus the sprayed film 42b is removed by a physical effect. A projection area of the blast particles 200 is set to an area, including the mask material 101, over the surface FS1 so as not to cover the surface FS2.

At this time, a portion of the anodized film 42a, which is not covered with the mask material 101 but covered with the sprayed film 42b, is also removed. A position of the end EP1 of the anodized film 42a is therefore slightly retracted and moved to a position aligned with the mask material 101.

Subsequently, as illustrated in FIG. 6E, a new sprayed film 42b is formed by spraying on the surface FS1 exposed from the mask material 101. A method and a condition for forming the new sprayed film 42b are the same as those described with reference to FIG. 5B. A direction in which the semi-molten particles 300 are blown to the surface FS1 of the base material 41 is perpendicular to the surface FS1. Subsequently, the mask material 101 is removed. Since the sprayed film 42b can also be restored in this way in the second embodiment, the inner wall member 40 is restored into the state of FIG. 6C.

The newly formed sprayed film 42b in FIG. 6E has an end EP3 located on the anodized film 42a formed on the surface FS1. A position of the end EP3 corresponds to the position of the end EP2 of the sprayed film 42b in FIG. 6C. The position of the end EP3 further corresponds to the position of the end EP1 of the anodized film 42a retracted as in FIG. 6D.

After that, if the inner wall member 40 is exposed to the plasma 3 again and the sprayed film 42b is, for example, changed in properties, the steps of FIGS. 6C to 6E are repeated, thereby the sprayed film 42b can be restored and in turn the inner wall member 40 can be restored

In the second embodiment, the jig, which is a metal member having a shape following the step shape, is used as the mask material 101. As a result, the mask material 101 can be quickly placed only by fitting the mask material 101 to the surface FS1 and the side surface SS1, i.e., fitting the mask material 101 to the step. Since the shape of the mask material 101 is unchanged, the position of the end EP1 of the anodized film 42a can be fixed at any time, and thus a position of the end EP3 of the newly formed sprayed film 42b can be fixed.

As described with reference to FIG. 6D, the position of the end EP1 of the anodized film 42a is slightly retracted during first restoration of the sprayed film 42b. During second or subsequent restoration of the sprayed film 42b, however, since the shape of the mask material 101 is unchanged, the position of the end EP1 is not changed, i.e., the same before and after restoration. Specifically, even if the sprayed film 42b is repeatedly restored by repeating the steps of FIGS. 6C to 6E, the position of each of the ends EP1 and EP3 is fixed at any time. In the second embodiment, therefore, it is also possible to prevent area of the anodized film 42a from being decreased, and suppress generation of a foreign matter within the processing chamber 4. In addition, it is possible to provide a sprayed film 42b, of which the various parameters such as thickness and area are each substantially the same before and after respraying.

Although the invention has been specifically described according to the embodiments, the invention should not be limited thereto, and various modifications or alterations can be made within the scope without departing from the gist of the invention.

In the first embodiment, for example, a jig having an unchanged shape, such as the mask material 101, can also be used in place of the mask material 100. However, the inner wall member 40 may have a different shape depending on a specification of the plasma processing apparatus 1. In such a case, a jig fit to such a shape needs to be prepared. Further, a portion, at which the anodized film 42a is in contact with the sprayed film 42b, is not always a portion at which a jig is easy to be accurately placed (for example, the portion as in FIG. 6D). For the mask material 100 such as a resin tape as in the first embodiment, a new jig need not be prepared, and thus the mask material 100 is easily applied to any of inner wall members 40 having various shapes.

In other words, the second embodiment is better than the first embodiment in accuracy at which the position of the end EP1 of the anodized film 42a is made coincident with the position of the end EP3 of the new sprayed film 42b and in speed to place the mask material. On the other hand, the first embodiment is better than the second embodiment in versatility of the mask material.

### LIST OF REFERENCE SIGNS

1 Plasma processing apparatus
2 Vacuum container
3 Plasma
4 Processing chamber
5 Stage
6 Window member
7 Plate
8 Through-hole
9 Gap
10 Impedance matching device
11 High-frequency power source
12 Waveguide
13 Magnetron oscillator
14 Solenoid coil
15 solenoid coil
16 Pipe
17 Gas supply unit
18 Pressure regulating plate
19 Pressure detector
20 Turbo molecular pump
21 Dry pump
22 Exhaust pipe
23 to 25 Bulb
30 Base material
40 Inner wall member (earth electrode)
40a Upper part
40b Middle part
40c Lower part
41 Base material
42 Coating
42a Anodized film
42b Sprayed film
50 Region
100 Mask material (resin tape)
101 Mask material (jig)
200 Blast particles
300 Semi-molten particles
EP1 to EP3 End
ES1, FS2 Surface
SS1 Side surface
WF Wafer (material to be processed)

1. A method for restoring an inner wall member provided on an inner wall of a processing chamber of a plasma processing apparatus, the processing chamber being a processing chamber in which plasma processing is performed,
the inner wall member comprising:
a base material having a first surface, a second surface located at a higher position than the first surface, and a first side surface connecting the first surface to the second surface;
an anodized film formed on the first surface and the first side surface, and having a first end located on the first side surface; and
a first sprayed film formed on the first surface, the first side surface, and the second surface so as to cover the first end, and having a second end located on the anodized film formed on the first surface,
the method comprising the steps of:
(a) covering by a mask material the anodized film exposed from the first sprayed film;
(b) after the step (a), performing blasting on the first sprayed film to remove the first sprayed film on the second surface while partially leaving the first sprayed film on the first surface and the first side surface to allow the anodized film being not covered with the mask material to be covered by the first sprayed film;
(c) after the step (b), forming a second sprayed film by spraying on the left first sprayed film and the second surface; and
(d) after the step (c), removing the mask material.

2. The method according to claim 1, wherein in the step (b), the blasting is performed by projecting blast particles from a direction running from the second surface toward the first surface and inclined at a certain angle with respect to the first surface.

3. The method according to claim 1, wherein in the step (a), the mask material is in contact with the second end.

4. The method according to claim 3, wherein the second sprayed film has a third end located on the anodized film formed on the first surface, and
a position of the third end corresponds to a position of the second end of the first sprayed film.

5. The method according to claim 1, wherein the mask material includes a resin tape.

6. The method according to claim 1, wherein the first sprayed film and the second sprayed film are made of the same material.

7. The method according to claim 1, wherein the base material has a cylinder shape having a certain thickness between inner circumference and outer circumference of the cylinder, and
the first surface, the first side surface, and the second surface are provided on an outer circumferential side of the base material.

8. A method for restoring an inner wall member provided on an inner wall of a processing chamber of a plasma processing apparatus, the processing chamber being a processing chamber in which plasma processing is performed,
the inner wall member comprising:
a base material having a first surface, a second surface located at a higher position than the first surface, and a first side surface connecting the first surface to the second surface;
an anodized film formed on the first surface, the first side surface, and the second surface, and having a first end located on the first surface; and
a first sprayed film formed on the first surface so as to cover the first end, and having a second end located on the anodized film formed on the first surface,
the method comprising the steps of:
(a) covering by a mask material the anodized film exposed from the first sprayed film and formed at least on the first surface and the first side surface;
(b) after the step (a), performing blasting on the first sprayed film to remove the first sprayed film on the first surface;
(c) after the step (b), forming a second sprayed film by spraying on the first surface exposed from the mask material; and
(d) after the step (c), removing the mask material.

9. The method according to claim 8, wherein in the step (a), the mask material is in contact with the second end.

10. The method according to claim 9, wherein the second sprayed film has a third end located on the first surface, and
a position of the third end corresponds to a position of the second end of the first sprayed film.

11. The method according to claim 8, wherein the mask material is a jig having a shape following respective shapes of the first surface and the first side surface.

12. The method according to claim 8, wherein the first sprayed film and the second sprayed film are made of the same material.

13. The method according to claim 8, wherein the base material has a cylinder shape having a certain thickness between inner circumference and outer circumference of the cylinder, and
the first surface, the first side surface, and the second surface are provided on an outer circumferential side of the base material.

14. The method according to claim 8, wherein in the step (b), a portion of the anodized film is also removed, the portion being not covered with the mask material but covered with the first sprayed film, and a position of the first end is retracted.

15. The method according to claim 14, further comprising the steps of:
(e) after the step (d), exposing the inner wall member to plasm;
(f) after the step (e), covering by the mask material the anodized film exposed from the second sprayed film and formed at least on the first surface and the first side surface;
(g) after the step (f), performing blasting on the second sprayed film to remove the second sprayed film on the first surface;
(h) after the step (g), forming a third sprayed film by spraying on the first surface exposed from the mask material; and
(i) after the step (h), removing the mask material,
wherein a position of the first end after the step (i) corresponds to a position of the first end before the step (f).
